(19) United States
(12) Patent Application Publication
(10) Pub. No.: US 2026/0349175 A1
(43) Pub. Date: Nov. 5, 2026

(54) OPTICAL DEVICE AND METHOD OF MANUFACTURING THE SAME

(71) Applicant: Taiwan Semiconductor Manufacturing Co., Ltd., Hsinchu (TW)

(72) Inventor: Ming-Fa Chen, Taichung City (TW)

(21) Appl. No.: 19/739,240

(22) Filed: Jul. 13, 2026

Related U.S. Application Data
(62) Division of application No. 18/364,846, filed on Aug. 3, 2023.

(51) Int. Cl. G02B 6/136; G02B 6/124; H10W 90/00; G02B 6/12; H10W 72/20; H10W 72/29; H10W 72/90; H10W 80/00

(52) U.S. Cl. CPC G02B 6/136; G02B 6/124; H10W 90/00; G02B 2006/12104; G02B 2006/12107; H10W 72/222; H10W 72/242; H10W 72/252; H10W 72/29; H10W 72/923; H10W 72/941; H10W 72/944; H10W 72/951; H10W 72/952; H10W 72/953; H10W 72/957; H10W 80/327; H10W 90/731; H10W 90/792; H10W 90/794

(57) ABSTRACT

A method includes forming an optical interposer, comprising: forming an optical device layer over a front-side of a first substrate, the optical device layer comprising a grating coupler; forming a first interconnect structure over the optical device layer, the first interconnect structure comprising conductive features and dielectric layers; etching an opening through the dielectric layers to expose the grating coupler; filling the opening with an oxide layer; forming a first bond layer over a back-side of the first substrate, the first bond layer comprising first bond pads and a first dielectric bond layer; and attaching a semiconductor device to the optical interposer, the semiconductor device comprising: an active device layer over a front-side of a second substrate; a second interconnect structure over the active device layer; and a second bond layer over the second interconnect structure, the second bond layer comprising second bond pads and a second dielectric bond layer.

### PRIORITY CLAIM AND CROSS-REFERENCE

This application is a divisional of U.S. Patent Application No. 18/364,846, entitled “OPTICAL DEVICE AND METHOD OF MANUFACTURING THE SAME,” filed on Aug. 3, 2023, which application is incorporated herein by reference.

### BACKGROUND

Electrical signaling and processing are one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10 illustrate intermediate stages in the formation of an optical interposer, in accordance with some embodiments.

FIG. 11 illustrates intermediate stages in the formation of a semiconductor device, in accordance with some embodiments.

FIGS. 12-15 illustrate intermediate stages in the formation of an optical package, in accordance with some embodiments.

FIGS. 16-17 illustrate intermediate stages in the formation of an optical interposer, in accordance with some embodiments.

FIG. 18 illustrates intermediate stages in the formation of a semiconductor device, in accordance with some embodiments.

FIGS. 19-21 illustrate intermediate stages in the formation of an optical package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments provided herein are discussed with respect to certain embodiments in which a photonic integrated circuit (PIC) device (e.g., an optical interposer) is formed and an electronic integrated circuit (EIC) device (e.g., a semiconductor device) is bonded to the PIC device to form an optical package such as a compact universal photonic engine (COUPE). In some embodiments, the optical interposer includes a plurality of PIC devices in wafer form, and the EIC device may be singulated from a wafer and bonded to the PIC device in a face-to-back layout. Various advantages may be achieved by utilizing the face-to-back layout. It should be appreciated that the embodiments presented herein are intended to be illustrative and are not intended to limit the embodiments to the precise descriptions as discussed. Rather, the embodiments discussed may be incorporated into a wide variety of implementations, and all such implementations are fully intended to be included within the scope of the embodiments.

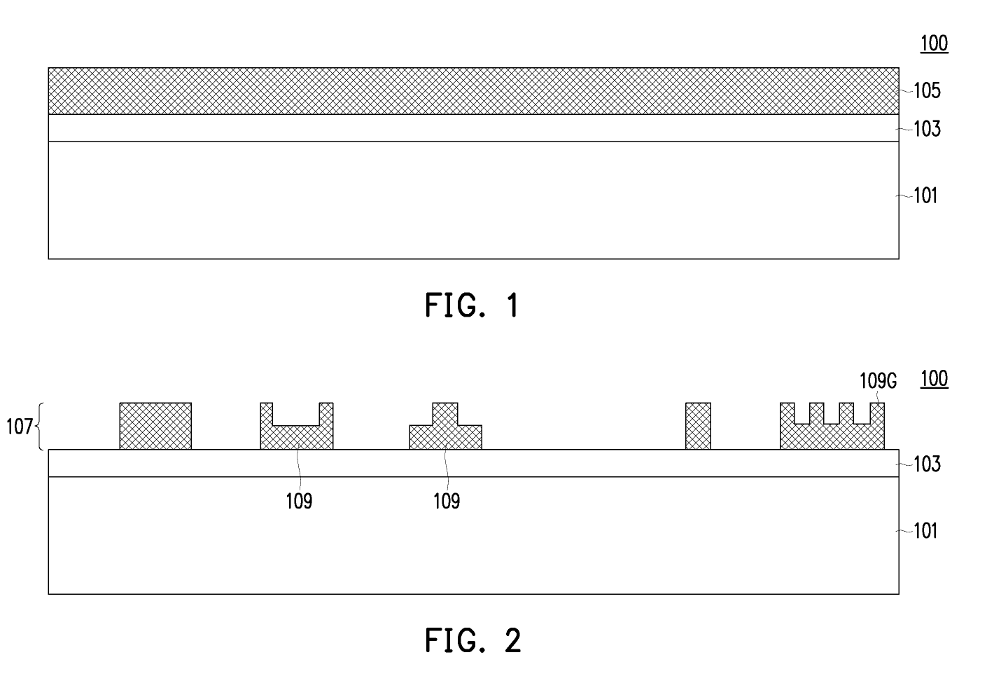

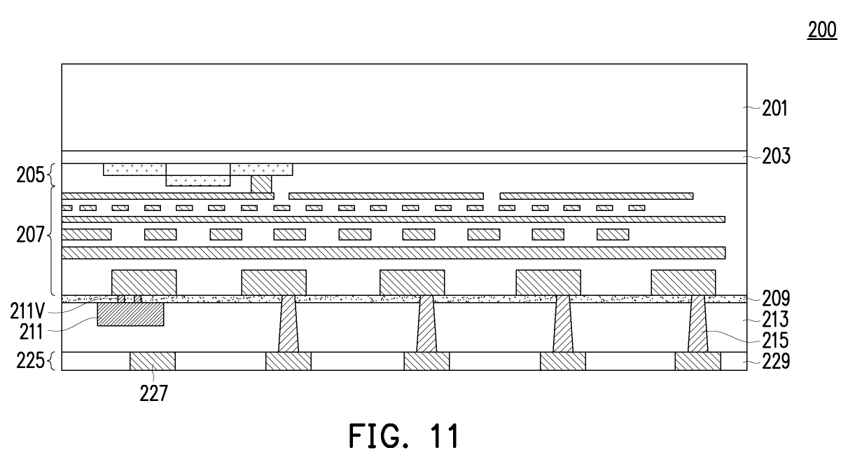

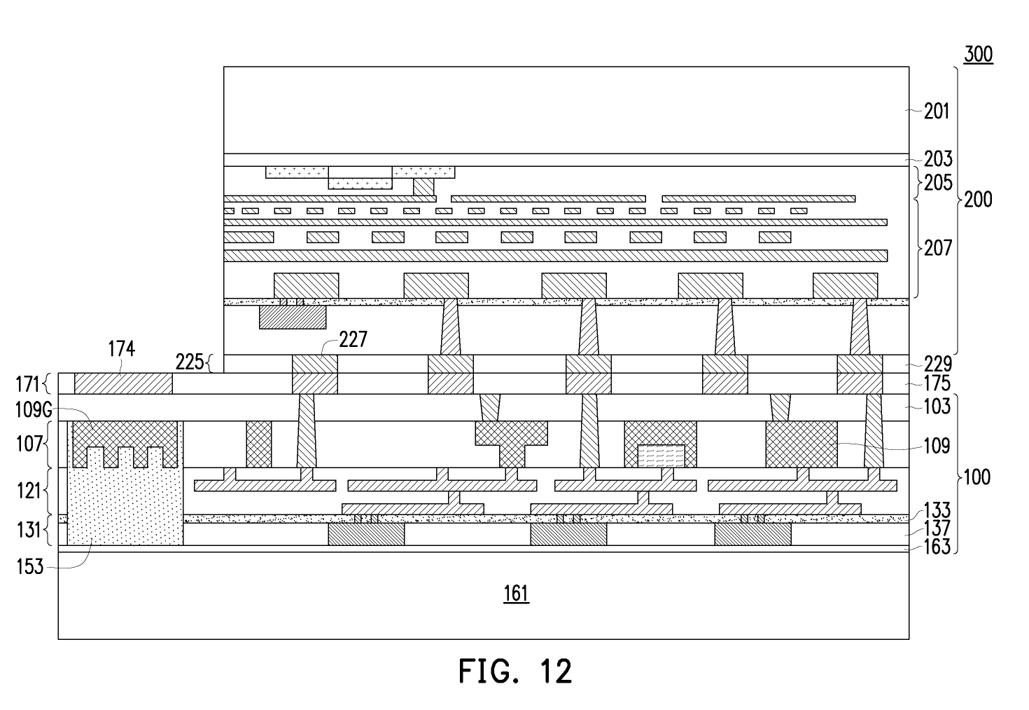

FIGS. 1-15 represent exemplary embodiments of forming and combining a first optical interposer 100 and a first semiconductor device 200 to form a first optical package 300. FIGS. 1-10 represent exemplary embodiments for the first optical interposer 100, FIG. 11 represents exemplary embodiments for the first semiconductor device 200, and FIGS. 12-15 represent exemplary embodiments for processing these components to form the first optical package 300.

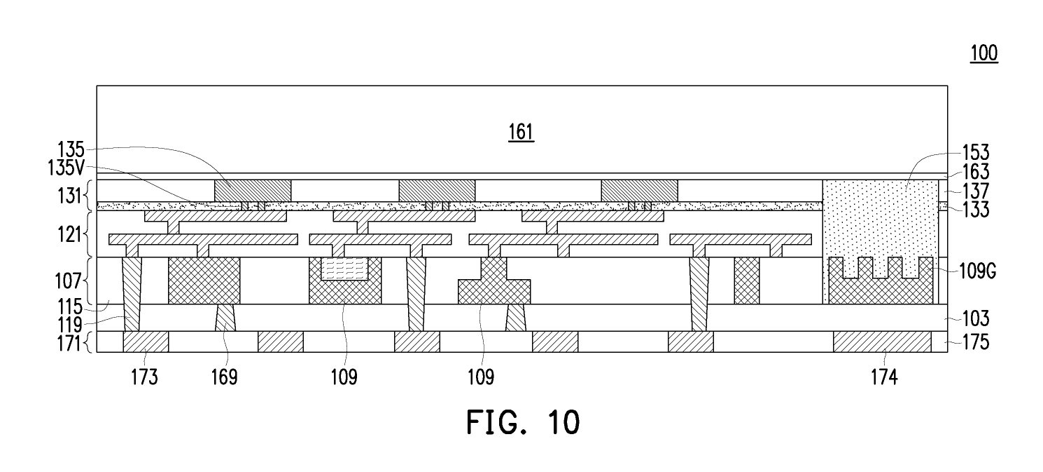

FIG. 1 illustrates an initial structure of a partially formed first optical interposer 100 (substantially assembled in FIG. 10), in accordance with some embodiments. In the illustrated embodiments, as discussed above, the first optical interposer 100 includes a photonic integrated circuit (e.g., being a PIC device) and comprises at this stage a substrate 101, a first insulator layer 103, and a layer of material 105 for an active layer 107 of optical components 109 (see FIG. 2). In an embodiment, near a beginning of the manufacturing process of the first optical interposer 100, the substrate 101, the first insulator layer 103, and the layer of material 105 for the active layer 107 of optical components 109 may collectively be part of a silicon-on-insulator (SOI) substrate. The substrate 101 may be a semiconductor material such as silicon or germanium, a dielectric material such as glass, or any other suitable material that allows for structural support of overlying devices and other components discussed further below.

The first insulator layer 103 may be a dielectric layer that separates the substrate 101 from the overlying material 105 (e.g., subsequently the active layer 107) and can additionally, in some embodiments, serve as a portion of cladding material that surrounds the subsequently manufactured optical components 109 (discussed further below). In an embodiment, the first insulator layer 103 may be silicon oxide, silicon nitride, germanium oxide, germanium nitride, combinations of these, or the like, formed using a method such as implantation (e.g., to form a buried oxide (BOX) layer) or else may be deposited onto the substrate 101 using a deposition method such as chemical vapor deposition, atomic layer deposition, physical vapor deposition, combinations of these, or the like. However, any suitable material and method of manufacture may be used.

The material 105 for the active layer 107 is initially (prior to patterning) a conformal layer of material that will be used to begin manufacturing the active layer 107 of the optical components 109. In an embodiment, the material 105 for the active layer 107 may be a translucent material that can be used as a core material for the desired optical components 109, such as a semiconductor material such as silicon, germanium, silicon germanium, combinations of these, or the like, while in other embodiments the material 105 for the active layer 107 may be a dielectric material such as silicon nitride or the like, although in other embodiments the material 105 for the active layer 107 may be III-V materials, lithium niobate materials, or polymers. In embodiments in which the material 105 of the active layer 107 is deposited, the material 105 for the active layer 107 may be deposited using a method such as epitaxial growth, chemical vapor deposition, atomic layer deposition, physical vapor deposition, combinations of these, or the like. In other embodiments in which the first insulator layer 103 is formed using an implantation method, the material 105 of the active layer 107 may initially be part of the substrate 101 prior to the implantation process to form the first insulation layer 103. However, any suitable materials and methods of manufacture may be utilized to form the material 105 of the active layer 107.

FIG. 2 illustrates that, once the material 105 for the active layer 107 is ready, the optical components 109 for the active layer 107 are manufactured using the material 105 for the active layer 107. In accordance with some embodiments, the optical components 109 of the active layer 107 may include such components as optical waveguides (e.g., ridge waveguides, rib waveguides, buried channel waveguides, diffused waveguides, etc.), couplers (e.g., grating couplers, edge couplers, etc.), directional couplers, photodetectors, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable optical components 109 may be used. As illustrated, among the optical components 109, the couplers may include grating couplers 109G.

To begin forming the active layer 107 of optical components 109 from the initial material 105, the material 105 for the active layer 107 may be patterned into the desired shapes for the active layer 107 of optical components 109. In an embodiment, the material 105 for the active layer 107 may be patterned using, e.g., one or more photolithographic masking and etching processes. However, any suitable method of patterning the material 105 for the active layer 107 may be utilized. For some of the optical components 109, such as waveguides, edge couplers, or the grating couplers 109G, the patterning process may be all or at least most of the manufacturing that is used to form these optical components 109 components.

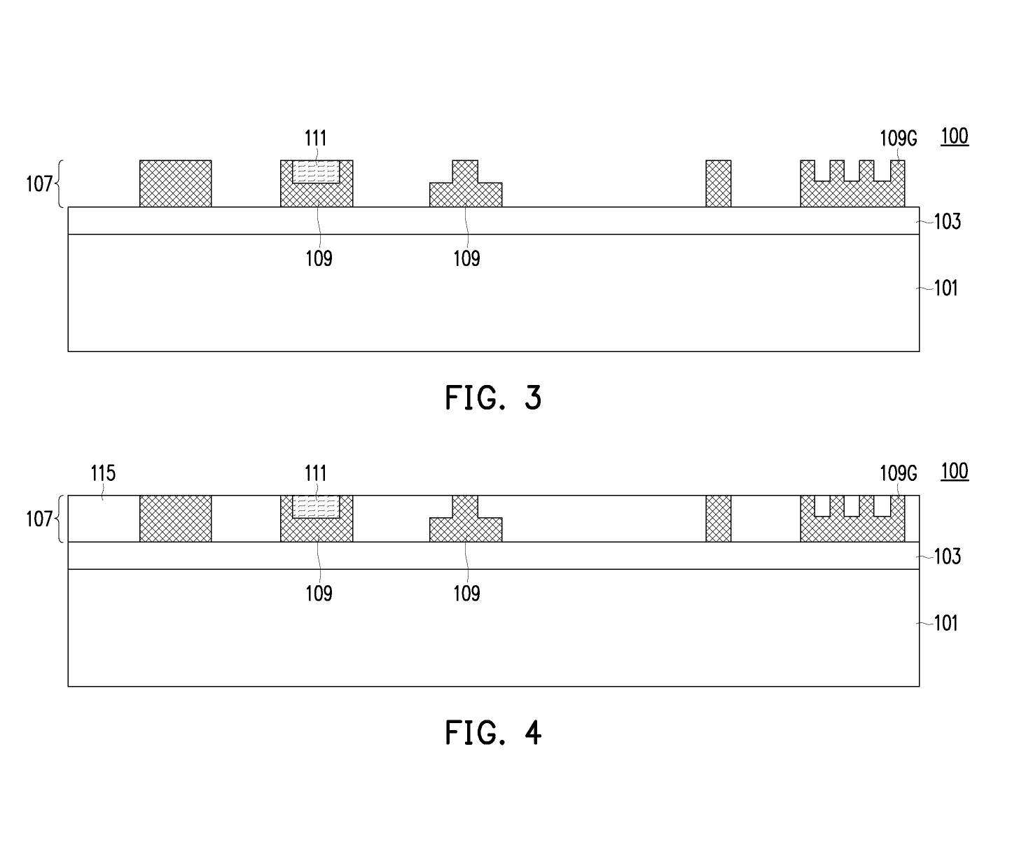

FIG. 3 illustrates that, for those components that utilize further manufacturing processes, such as Mach-Zehnder silicon-photonic switches that utilize resistive heating elements, additional processing may be performed either before or after the patterning of the material for the active layer 107. For example, implantation processes, additional deposition and patterning processes for different materials (e.g., resistive heating elements, III-V materials for converters), combinations of all of these processes, or the like, can be utilized to help further the manufacturing of the various desired optical components 109. In a particular embodiment, an epitaxial deposition of a semiconductor material 111 such as germanium (e.g., used for electricity/optics signal modulation and transversion) may be performed on a patterned portion of the material 105 of the active layer 107. In such an embodiment the semiconductor material 111 may be epitaxially grown in order to help manufacture, e.g., a photodiode for an optical-to-electrical converter. All such manufacturing processes and all suitable optical components 109 may be manufactured, and all such combinations are fully intended to be included within the scope of the embodiments.

FIG. 4 illustrates that, once the individual optical components 109 of the active layer 107 have been formed, a second insulating layer 115 of the active layer 107 may be deposited to cover the optical components 109 and provide additional cladding material. In an embodiment, the second insulator layer 115 may be a dielectric layer that separates the individual components of the active layer 107 from each other and from the overlying structures and can additionally serve as another portion of cladding material that surrounds the optical components 109. In an embodiment, the second insulator layer 115 may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the second insulating layer 115 has been deposited, the material may be planarized using, e.g., a chemical mechanical polishing process in order to either planarize a top surface of the second insulating layer 115 (in embodiments in which the second insulating layer 115 is intended to fully cover the optical components 109) or else planarize the second insulating layer 115 with top surfaces of the optical components 109. However, any suitable material and method of manufacture may be used.

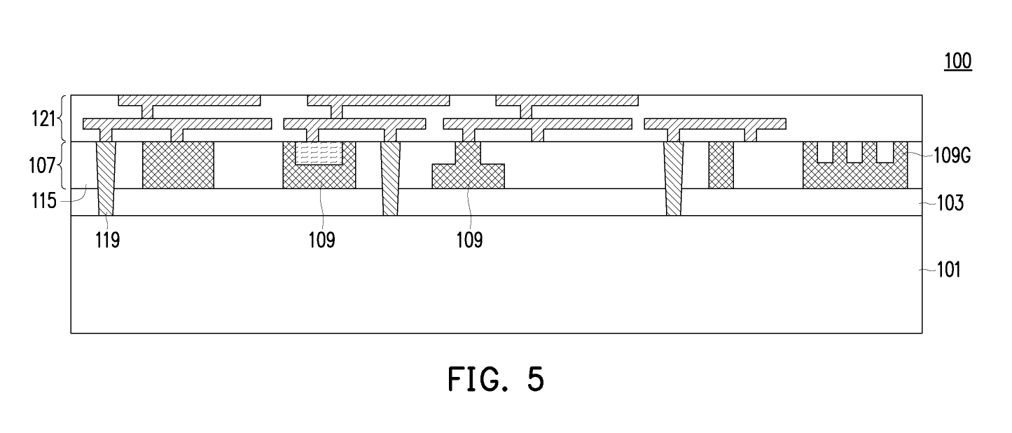

FIG. 5 illustrates that, once the optical components 109 of the active layer 107 have been manufactured and the second insulating layer 115 has been formed, through device vias (TDVs) 119 are formed through the active layer 107 and the first insulating layer 103. In addition, an interconnect structure 121 is formed in order to electrically connect the TDVs 119 and the active layer 107 of optical components 109 to control circuitry, to one another, and to subsequently attached devices (not illustrated in FIG. 5 but illustrated and described further below with respect to FIGS. 11-15). In various embodiments (not specifically illustrated), the TDVs 119 may be formed prior to forming the active layer 107 or after forming some or all of the interconnect structure 121. In addition, the TDVs 119 may extend to, or partially into, the substrate 101.

In an embodiment, the interconnect structure 121 is formed of alternating layers of dielectric and conductive material and may be formed through any suitable processes (such as deposition, damascene, dual damascene, etc.). In particular embodiments, there may be multiple layers of metallization or conductive features used to interconnect the various optical components 109, but the precise number of metallization layers of the interconnect structure 121 is dependent upon the design of the first optical interposer 100.

Additionally, during the manufacture of the interconnect structure 121, additional optical components (not specifically illustrated) may be formed as part of the interconnect structure 121. In some embodiments, the additional optical components of the interconnect structure 121 may include similar components as discussed above in connection with the optical components 109, such as couplers (e.g., edge couplers, grating couplers, etc.) for connection to outside signals, optical waveguides (e.g., ridge waveguides, rib waveguides, buried channel waveguides, diffused waveguides, etc.), photodetectors, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable optical components may be used for the additional optical components.

In some embodiments, the additional optical components may be formed by initially depositing a material for the additional optical components. In an embodiment, the material for the additional optical components may be a dielectric material such as silicon nitride, silicon oxide, combinations of these, or the like, or a semiconductor material such as silicon, deposited using a deposition method such as chemical vapor deposition, atomic layer deposition, physical vapor deposition, combinations of these, or the like. However, any suitable material and any suitable method of deposition may be utilized.

Once the material for the additional optical components has been deposited or otherwise formed, the material may be patterned into the desired shapes for the additional optical components. In an embodiment, the material of the additional optical components may be patterned using, e.g., one or more photolithographic masking and etching processes. However, any suitable method of patterning the material for the additional optical components may be utilized.

For some of the additional optical components, such as waveguides or couplers, the patterning process may be all or at least most manufacturing that is used to form these components. Additionally, for those components that utilize further manufacturing processes, such as Mach-Zehnder silicon-photonic switches that utilize resistive heating elements, additional processing may be performed either before or after the patterning of the material for the additional optical components, similarly as described above in connection with the optical components 109. For example, implantation processes, additional deposition and patterning processes for different materials, combinations of all of these processes, or the like, and can be utilized to help further the manufacturing of the various desired additional optical components. All such manufacturing processes and all suitable additional optical components may be manufactured, and all such combinations are fully intended to be included within the scope of the embodiments.

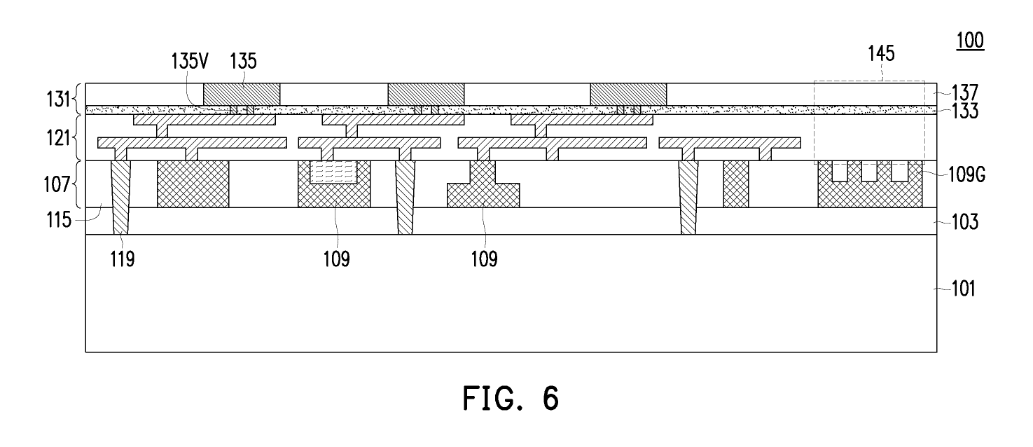

FIG. 6 illustrates formation of a metal pad layer 131 over the interconnect structure 121, in accordance with some embodiments. The metal pad layer 131 may include metal pads 135 and dielectric layers (e.g., a first passivation layer 133 and a second passivation layer 137). For example, the dielectric layers may include one or more layers of silicon nitride, silicon oxide, silicon oxynitride, the like, or a combination thereof. In some embodiments, the first passivation layer 133 may be a nitride and the second passivation layer 137 may be an oxide. Each of the dielectric layers may be formed using a suitable process such as chemical vapor deposition (CVD), plasma-enhanced chemical vapor deposition (PECVD), physical vapor deposition (PVD), atomic layer deposition (ALD), the like, or a combination thereof. In some embodiments, the first passivation layer 133 is formed over the interconnect structure 121, and one or more openings are formed in the first passivation layer 133. The first passivation layer 133 may comprise one or more layers of one or more materials. The openings in the first passivation layer 133 may be formed using a suitable photolithographic and etching process. The openings are formed to expose portions of the conductive material of the interconnect structure 121 for electrical connection.

The metal pads 135 are formed over the first passivation layer 133 in accordance with some embodiments. In addition, the metal pads 135 may be formed extending through the openings in the first passivation layer 133 to make electrical connection with conductive material of the interconnect structure 121. In some embodiments, the metal pads 135 may be formed by first depositing a blanket layer of a conductive material such as aluminum. For example, CVD, PVD, or the like may be used to deposit a layer of aluminum over the first passivation layer 133, the openings, and the exposed conductive material of the interconnect structure 121. A photoresist layer (not separately illustrated) may then be formed over the aluminum layer and the aluminum layer may be etched to form the metal pads 135. The metal pads 135 formed from aluminum in this manner may be referred to as “aluminum pads.”

In some embodiments, the metal pads 135 are formed by first forming a seed layer (not specifically illustrated) over the first passivation layer 133 and the openings. For example, the seed layer may be a metal layer comprising one or more layers, which may be formed of different materials. The seed layer may be formed using, for example, PVD or the like. A photoresist is formed and patterned on the seed layer and conductive material is formed in the openings of the photoresist and on the exposed portions of the seed layer. In some embodiments, the conductive material may be formed using a plating process, such as using an electroplating or electroless plating process, or the like. The conductive material may include one or more materials such as copper, titanium, tungsten, gold, cobalt, the like, or a combination thereof. The photoresist and portions of the seed layer on which the conductive material is not formed are then removed using, for example, a suitable ashing or stripping process, such as using an oxygen plasma or the like. Once the photoresist is removed, remaining exposed portions of the seed layer may be removed using an acceptable etching process, such as a wet etching process or a dry etching process. The remaining portions of the seed layer and conductive material form the metal pads 135. As illustrated, in some embodiments, via portions 135V of the metal pads 135 extend through the openings in the first passivation layer 133 to make contact with the conductive material of the interconnect structure 121. The metal pads 135 may be formed using other techniques in other embodiments, and all such techniques are considered within the scope of this disclosure. In some embodiments, the via portions 135V may be first formed through the first passivation layer 133, and the metal pads 135 may be subsequently formed over the first passivation layer 133 and the via portions 135V. As such, the via portions 135V and the metal pads 135 may be formed of same or different materials.

In some embodiments, some of the metal pads 135 that are electrically connected to the interconnect structure 121 may be used as test pads before additional processing steps are performed. For example, the metal pads 135 may be probed as part of a wafer-acceptance-test, a circuit test, a Known Good Die (KGD) test, or the like. The probing may be performed to verify the functionality of the active or passive devices of the active layer 107 or the various electrical connections within the integrated circuit. For example, the probing may be performed by contacting a probe needle (not specifically illustrated) to the metal pads 135.

In some embodiments, the conductive material of the metal pads 135 may be different than the conductive material of the interconnect structure 121. For example, the metal pads 135 may be aluminum and the conductive material of the interconnect structure 121 may be copper, though other conductive materials may be used.

Still referring to FIG. 6, a second passivation layer 137 is formed over the first passivation layer 133 and the metal pads 135. The second passivation layer 137 may be formed from one or more layers of one or more dielectric materials, such as silicon oxide, silicon nitride, silicon oxynitride, silicon carbonitride, SiOC, SiOCH, SiCH, the like, or a combination thereof. In some embodiments, the second passivation layer 137 may be formed from phosphosilicate glass (PSG), borosilicate glass (BSG), boron-doped phosphosilicate glass (BPSG), fluorine-doped silicate glass (FSG), tetraethyl orthosilicate (TEOS), the like, or a combination thereof. The second passivation layer 137 may be formed using a deposition process such as CVD, PECVD, PVD, ALD, the like, or a combination thereof. In some embodiments (not specifically illustrated), the second passivation layer 137 may be formed to have a thickness greater than a thickness of the metal pads 135 so that the material of the second passivation layer 137 laterally surrounds and covers top surfaces of the metal pads 135, and so that the second passivation layer 137 may be planarized without exposing the metal pads 135.

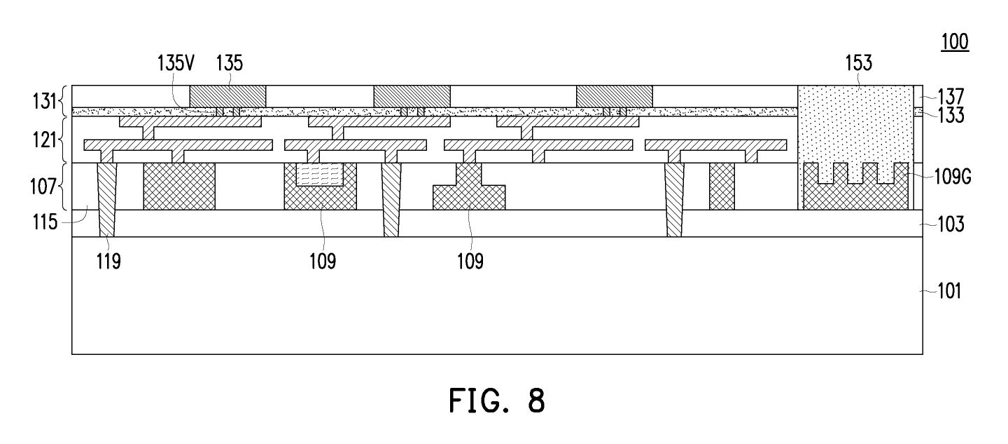

FIG. 6 additionally illustrates that, as part of the manufacturing of the first optical interposer 100, a region 145 within the interconnect structure 121 and the metal pad layer 131 remains free of conductive features (e.g., free of the conductive material of the interconnect structure 121 and the metal pads 135) and optical components (e.g., free of the optical components 109 or any other optical components within the interconnect structure 121). As illustrated, in an embodiment, the region 145 is a location directly above the grating couplers 109G. Corresponding portions of the dielectric layers of the interconnect structure 121 and the metal pad layer 131 will subsequently be removed and replaced with a homogeneous dielectric material (see FIG. 8) that is transparent to an optical signal (e.g., of at least the desired range(s) of light wavelengths). As such, the region 145 is formed by not placing optical components or conductive material directly above the grating couplers 109G within the corresponding layers.

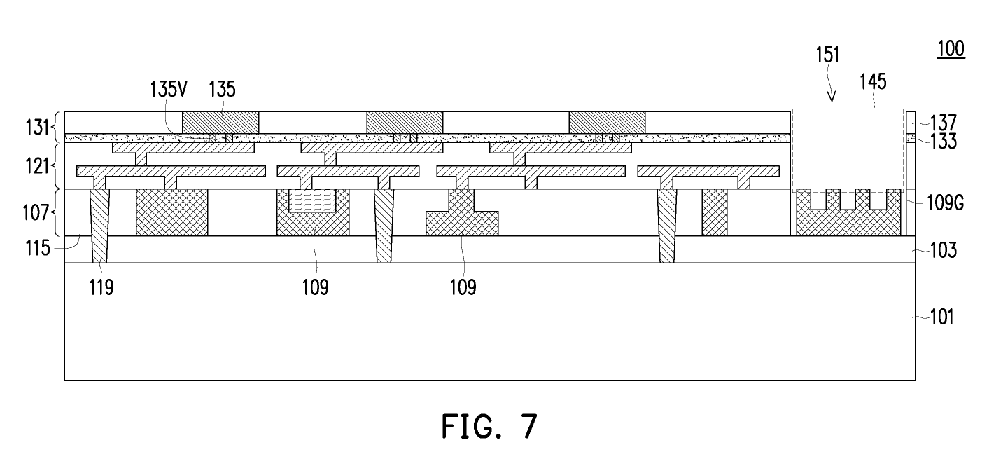

FIG. 7 illustrates forming an opening 151 in the region 145 and further through the active layer 107 to expose the grating couplers 109G. For example, material is removed from the second passivation layer 137, the first passivation layer 133, the dielectric layers of the interconnect structure 121, and, optionally, the second insulating layer 115 to the grating couplers 109G. In an embodiment, the removal of the material may be performed using, for example, anisotropic etching processes, isotropic etching processes, or combinations thereof. For example, the etching processes may include one or more reactive ion etching processes. However, any suitable removal process or combination of removal processes, may be utilized. In some embodiments (not specifically illustrated), the opening may have a shallow depth wherein the grating couplers 109G remain covered by the second insulating layer 115 and some of the lower dielectric layers of the interconnect structure 121.

FIG. 8 illustrates filling the opening 151 with a dielectric fill layer 153. In some embodiments, the dielectric fill layer 153 may be an oxide or a nitride that is transparent to an optical signal at the desired wavelength or range(s) of wavelengths (e.g., a desired range of light wavelengths). For example, the dielectric fill layer 153 may be a continuous dielectric region, such as a continuous oxide region. For example, the dielectric fill layer 153 may be formed from TEOS, PSG, BSG, BPSG, FSG, the like, or a combination thereof. The dielectric fill layer 153 may be formed using a deposition process such as CVD, PECVD, PVD, ALD, the like, or a combination thereof. Although not specifically illustrated, in some embodiments, the opening 151 may be formed before depositing the second passivation layer 137, and the dielectric fill layer 153 may be formed simultaneously with and of the same material as the second passivation layer 137.

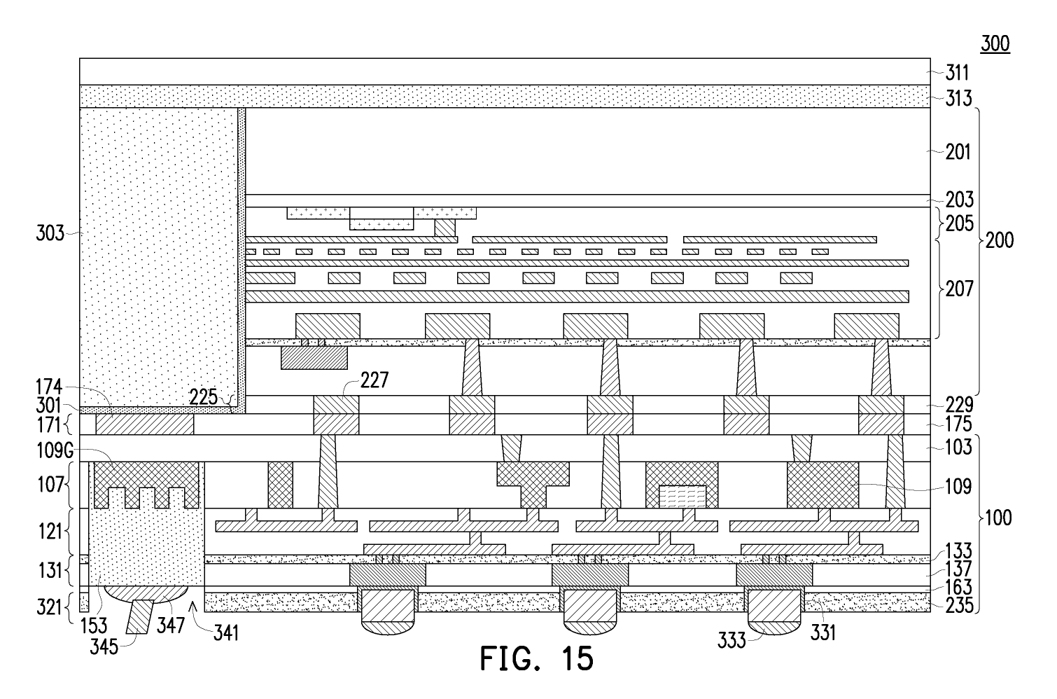

As discussed above, in some embodiments (not specifically illustrated), the opening 151 (see FIG. 7) and the dielectric fill layer 153 may extend to a depth that does not reach the grating couplers 109G. As such, other layers such as some of the dielectric layers of the interconnect structure 121 and the second insulating layer 115 may remain interposed between the dielectric fill layer 153 and the grating couplers 109G. It should be noted that these other layers are thin enough (and perhaps of a transparent or translucent material) to allow an optical signal to pass between the dielectric fill layer 153 and the grating couplers 109G (see FIG. 15).

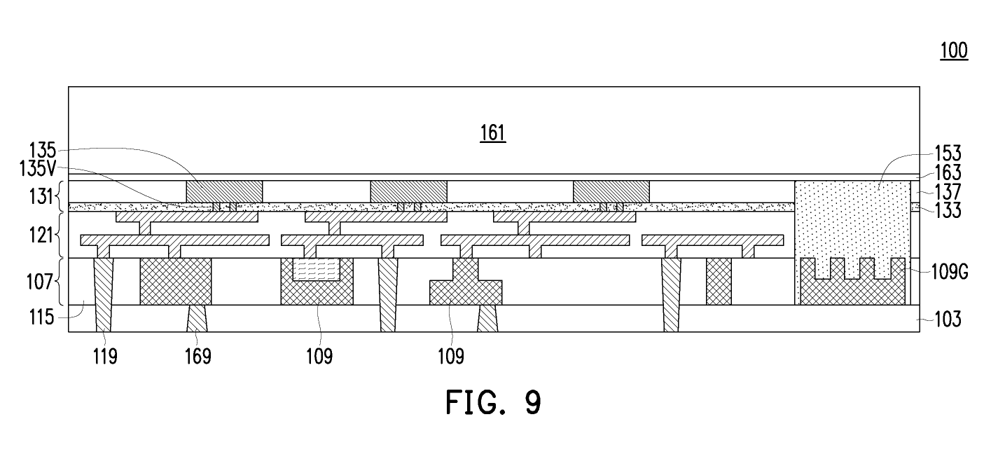

FIG. 9 illustrates that, once the metal pads 135 have been formed and the dielectric fill layer 153 has been deposited (e.g., and, optionally, after the first optical interposer 100 has undergone initial testing), a first carrier substrate 161 is attached to the first optical interposer 100. In an embodiment, an adhesive layer 163 along the first optical interposer 100 and the first carrier substrate 161 facilitates the attachment. In some embodiments, the adhesive layer 163 includes bonding layers on each of the components that form a dielectric-to-dielectric bond with one another. For example, as discussed below, a first bonding layer may first be formed over the first optical interposer 100 (e.g., over the second passivation layer 137 and the dielectric fill layer 153), and the first bonding layer may be used for a dielectric-to-dielectric bond with a second bonding layer disposed along the first carrier substrate 161. Note that in such embodiments, the bonding layers are illustrated collectively. In some embodiments, the second passivation layer 137 (and the dielectric fill layer 153) may be used for the dielectric-to-dielectric bonding with the second bonding layer along the first carrier substrate 161. In accordance with some embodiments, the bonding layers are each formed of dielectric materials such as silicon oxide, silicon nitride, or the like. The bonding layers may be deposited using any suitable method, such as CVD, high-density plasma chemical vapor deposition (HDPCVD), PVD, ALD, or the like. However, any suitable materials and deposition processes may be utilized. However, any suitable method of attaching the first carrier substrate 161 may be used.

FIG. 9 further illustrates removal of the substrate 101 to expose the through device vias (TDVs) 119 and, optionally, a back-side of the first insulator layer 103. In some embodiments (not specifically illustrated), some or all of the first insulator layer 103 may also be removed. In an embodiment, the substrate 101 and the first insulating layer 103 may be removed and/or thinned using a planarization process, such as a chemical mechanical polishing (CMP) process, a grinding process, one or more etching processes, combinations of these, or the like. However, any suitable method may be used in order to remove the substrate 101 and/or the first insulating layer 103. The remaining portion of the first insulating layer 103 may be referred to as a dielectric substrate of the first optical interposer 100. As illustrated, in an embodiment, the TDVs 119 extend through the active layer 107 and the first insulator layer 103 so as to provide a quick passage of power, data, and ground through the first optical interposer 100.

In some embodiments, back-side TDVs 169 may be formed by initially forming back-side TDV openings into the first insulator layer 103 to expose some of the optical components 109 of the active layer 107. The back-side TDV openings may be formed by applying and developing a suitable photoresist (not shown), and removing portions of the first insulator layer 103 that are exposed.

Once the back-side TDV openings have been formed within the first optical interposer 100, the back-side TDV openings may be lined with a liner. The liner may be, e.g., an oxide formed from TEOS or silicon nitride, although any suitable dielectric material may alternatively be used. The liner may be formed using a PECVD process, although other suitable processes, such as physical vapor deposition or a thermal process, may alternatively be used.

Once the liner has been formed along the sidewalls and bottom of the back-side TDV openings, a barrier layer (also not independently illustrated) may be formed and the remainder of the back-side TDV openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer (not shown), filling and overfilling the back-side TDV openings. Once the back-side TDV openings have been filled, excess liner, barrier layer, seed layer, and first conductive material outside of the back-side TDV openings may be removed through a planarization process such as CMP, although any suitable removal process may be used. As such, the remaining conductive material forms the back-side TDVs 169.

Optionally, in some embodiments (not specifically illustrated), once the substrate 101 and the first insulating layer 103 have been removed, an active layer of back-side optical components may be formed on the back-side of the active layer 107 (e.g., or of the first insulator layer 103, if present). For example, the back-side optical components may be formed using similar materials and similar processes as the optical components of the interconnect structure 121 as described above. The back-side optical components may be electrically coupled directly to the optical components 109 of the active layer 107 through the back-side TDVs or to the interconnect structure 121 through the TDVs 119.

In addition, optionally (not specifically illustrated), a back-side interconnect structure or redistribution structure may be formed in electrical connection with the TDVs 119 and the back-side TDVs 169. In an embodiment, the back-side interconnect structure may be formed as described above with respect to the interconnect structure 121, such as being alternating layers of dielectric and conductive materials using damascene processes, dual damascene process, or the like. In other embodiments, the back-side interconnect structure may be formed using a plating process to form and shape conductive material, and then the conductive material may be covered with a dielectric material. However, any suitable structures and methods of manufacture may be utilized.

FIG. 10 illustrates that, once the substrate 101 has been removed and the TDVs 119 have been exposed (and, optionally, the back-side TDVs 169 have been formed), a first bond layer 171 is formed over the TDVs 119 and the first insulator layer 103. In an embodiment, the first bond layer 171 may subsequently be used for a dielectric-to-dielectric and metal-to-metal bond (see FIG. 12). In accordance with some embodiments, the first bond layer 171 is formed of a first dielectric bond material 175 such as silicon oxide, silicon nitride, or the like. The first dielectric bond material 175 may be deposited using any suitable method, such as CVD, HDPCVD, PVD, ALD, or the like. However, any suitable materials and deposition processes may be utilized.

Once the first dielectric bond material 175 has been formed, first openings in the first dielectric bond material 175 are formed to expose the underlying TDVs 119 and back-side TDVs 169 in order to form first bond pads 173 within the first bond layer 171. Once the first openings have been formed within the first dielectric bond material 175, the first openings may be filled with a seed layer and a plate metal to form the first bond pads 173 within the first dielectric bond material 175. The seed layer may be blanket deposited over top surfaces of the first dielectric bond material 175 and the exposed conductive portions of the underlying layers and sidewalls of the openings and the second openings. In some embodiments, the seed layer may comprise a copper layer. The seed layer may be deposited using processes such as sputtering, evaporation, PECVD, or the like, depending upon the desired materials. The plate metal may be deposited over the seed layer through a plating process such as electrical or electro-less plating. The plate metal may comprise copper, a copper alloy, or the like. For example, the plate metal may be a fill material. A barrier layer (not separately illustrated) may be blanket deposited over top surfaces of the first dielectric bond material 175 and sidewalls of the openings and the second openings before the seed layer. The barrier layer may comprise titanium, titanium nitride, tantalum, tantalum nitride, or the like. Following the filling of the first openings, a planarization process, such as a CMP, is performed to remove excess portions of the seed layer and the plate metal, forming the first bond pads 173 within the first bond layer 171.

Still referring to FIG. 10, the process for forming the first bond pads 173 may include forming a reflective pad 174 in the first dielectric bond material 175. The reflective pad 174 serves to reflect optical signals to or from the grating couplers 109G. In an embodiment, the reflective pad 174 is located directly over the grating couplers 109G. In various embodiments, the reflective pad 174 may have a width substantially the same as or greater than either a footprint of the grating couplers 109G or a footprint of the dielectric fill layer 153 (e.g., overlapping in a plan view).

Additionally, the first bond layer 171 may also include additional optical components (not specifically illustrated) incorporated within the first bond layer 171. In such embodiments, prior to the deposition of the first dielectric bond material 175, these additional optical components may be manufactured using similar methods and similar materials as any of the optical components described above, such as by being waveguides and other structures formed at least in part through a deposition and patterning process. However, any suitable structures, materials and any suitable methods of manufacture may be utilized.

FIG. 11 illustrates a first semiconductor device 200 that will be bonded to the first optical interposer 100 (see FIG. 12). In some embodiments, the first semiconductor device 200 may include an electronic integrated circuit (EIC – e.g., a device without optical devices) and may comprise a semiconductor substrate 203, a layer of active devices 205 (e.g., an electronic device layer), and an overlying interconnect structure 207. In an embodiment, the semiconductor substrate 203 may be similar to the substrate 101 (e.g., a semiconductor material such as silicon or silicon germanium in a wafer form), the active devices 205 may include transistors, capacitors, resistors, and the like formed over the semiconductor substrate 203, and the interconnect structure 207 may be similar to the interconnect structure 121 (albeit, without optical components). However, any suitable devices may be utilized.

In some embodiments, the first semiconductor device 200 may be configured to work with the first optical interposer 100 for a desired functionality. In some embodiments the first semiconductor device 200 may be a logic die, a high bandwidth memory (HBM) module, an xPU, a 3DIC die, a CPU, a GPU, a SoC die, a MEMS die, combinations of these, or the like. Any suitable device with any suitable functionality may be used, and all such devices are fully intended to be included within the scope of the embodiments.

FIG. 11 further illustrates metal pads 211, bond pad vias 215, and a second bond layer 225 (e.g., including a second dielectric bond material 229 and second bond pads 227) in electrical connection with the interconnect structure 207, in accordance with some embodiments. As illustrated, the structure may further include a third passivation layer 209 and a fourth passivation layer 213 disposed around the metal pads 211. For example, the third passivation layer 209, the metal pads 211 (e.g., including via portions 211V), and the fourth passivation layer 213 may be formed using similar methods and similar materials as the first passivation layer 133, the metal pads 135, and the second passivation layer 137, respectively, as discussed above. In some embodiments, the fourth passivation layer 213 is deposited with a greater thickness over the metal pads 211, and the bond pad vias 215 are formed through the fourth passivation layer 213 and the third passivation layer 209 to be electrically connected to the interconnect structure 207. Further, the second bond layer 225 (e.g., the second dielectric bond material 229 and the second bond pads 227) may be formed using similar methods and similar materials as the first bond layer 171 (e.g., the first dielectric bond material 175 and the first bond pads 173).

In accordance with some embodiments, after forming the metal pads 211 and the fourth passivation layer 213, the bond pad vias 215 may be formed by initially forming openings to conductive features of the interconnect structure 207 and/or to the metal pads 211. The openings may be formed using acceptable photolithography and etching techniques. For example, the photolithography process may include forming a photoresist (not shown) over the fourth passivation layer 213, patterning the photoresist to correspond with the desired openings, extending the openings through the fourth passivation layer 213 and the third passivation layer 209 to expose the interconnect structure 207, and then removing the photoresist.

The bond pad vias 215 are then formed in the openings, in accordance with some embodiments. As illustrated, the bond pad vias 215 may have a tapered profile, such as linear tapered or concave tapered. In some embodiments, the formation of the bond pad vias 215 includes first forming a barrier layer (not separately illustrated) within the openings. The barrier layer may be, for example, a liner, a diffusion barrier layer, an adhesion layer, or the like. The barrier layer may include one or more layers comprising titanium, titanium nitride, tantalum, tantalum nitride, the like, or combinations thereof. The barrier layer may be deposited as a blanket layer over the dielectric layer 122 and within the openings. The barrier layer may be formed using a deposition process such as CVD, PECVD, PVD, the like, or combinations thereof.

The formation of the bond pad vias 215 may include depositing a conductive material over the barrier layer. The conductive material may include cobalt, copper, a copper alloy, titanium, silver, gold, tungsten, aluminum, nickel, the like, or combinations thereof. The conductive material of the bond pad vias 215 may be formed using a deposition process such as CVD, PECVD, PVD, the like, or combinations thereof. In some embodiments, the conductive material of the bond pad vias 215 is formed by depositing a seed layer (not shown) over the barrier layer, which may include copper, a copper alloy, titanium, or the like, and then filling the remainder of the openings using, for example, a plating process, an electro-less plating process, or the like. After forming the conductive material, a planarization process, such as a grinding process, a CMP process, or the like may be performed to remove excess material from a surface of the fourth passivation layer 213. The remaining barrier layer and conductive material thus form the bond pad vias 215. In this manner, the bond pad vias 215 may be formed using a single damascene process.

FIG. 11 further illustrates that a second bond layer 225 is formed over the interconnect structure 207 and the bond pad vias 215, similarly as described above in connection with the first bond layer 171. In an embodiment, the second bond layer 225 is used for a dielectric-to-dielectric and metal-to-metal bond with the first dielectric bond material 175. In accordance with some embodiments, the second bond layer 225 is formed of a second dielectric bond material 229 such as silicon oxide, silicon nitride, or the like. The second dielectric bond material 229 may be deposited using any suitable method, such as CVD, HDPCVD, PVD, ALD, or the like. In addition, openings are formed in the second dielectric bond material 229, and second bond pads 227 are formed in the openings. The second bond pads 227 may include a suitable seed layer formed by sputtering, evaporation, PECVD, or the like, and a fill material (e.g., a plate metal) may include copper, a copper alloy, or the like formed by electrical or electro-less plating. In some embodiments, the second bond pads 227 may further include a barrier layer comprising titanium, titanium nitride, tantalum, tantalum nitride, or the like. However, any suitable materials and deposition processes may be utilized for the second bond layer 225.

In addition, a support substrate 201 may be attached to the semiconductor substrate 203 using, e.g., an adhesive (not separately illustrated). In addition, in some embodiments, the support substrate 201 may be bonded using, e.g., a bonding process. Any suitable method of attaching the support substrate 201 may be used.

In some embodiments, a singulation process is performed along scribe line regions (not specifically labeled) to separate adjacent EICs of the first semiconductor device 200. The singulation process may include a dicing process, a sawing process, a laser process, the like, or a combination thereof. In some embodiments, singulated EICs that were probed and found to be Known Good Dies (KGDs), similarly as described above, are used in subsequent process steps to form an optical package, such as a compact universal photonic engine (COUPE).

FIGS. 12-15 illustrate attachment of the first semiconductor device 200 to the first optical interposer 100 to form a first optical package 300. As discussed above and in greater detail below, after attachment of these components, the first optical package 300 may undergo subsequent processing in order to form, for example, a COUPE device.

FIG. 12 illustrates bonding of the first semiconductor device 200 (e.g., singulated EIC device from the wafer) to the first optical interposer 100 (e.g., PIC device remaining as part of a wafer). In other embodiments, the first semiconductor device 200 may remain as a part of a wafer, while the first optical interposer 100 is first singulated from its wafer. In other embodiments, both the first semiconductor device 200 and the first optical interposer 100 may remain in wafer form for the bonding process.

As illustrated, the first semiconductor device 200 and the first optical interposer 100 are attached in a front-to-back layout. For example, the second bond layer 225 along the front-side of the first semiconductor device 200 is bonded to the first bond layer 171 along the back-side of the first optical interposer 100. In accordance with various embodiments, the second bond layer 225 and the first bond layer 171 may be bonded using a dielectric-to-dielectric and metal-to-metal bonding process. However, any other suitable bonding process may also be utilized.

In a particular embodiment which utilizes a dielectric-to-dielectric and metal-to-metal bonding process, the process may be initiated by activating the surfaces of the first bond layer 171 and the second bond layer 225. Activating the top surfaces of the first bond layer 171 and the second bond layer 225 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning process may be used, for example. In some embodiments, the activation process may comprise other types of treatments. The activation process assists in the bonding of the first bond layer 171 and the second bond layer 225.

After the activation process, the first optical interposer 100 and the first semiconductor device 200 may be cleaned using, e.g., a chemical rinse, and then the first semiconductor device 200 is aligned and placed into physical contact with the first optical interposer 100 in a chip-to-wafer alignment process. The first optical interposer 100 and the first semiconductor device 200 are then subjected to thermal treatment and contact pressure to bond the first optical interposer 100 and the first semiconductor device 200. For example, the first optical interposer 100 and the first semiconductor device 200 may be subjected to a pressure of about 200 kPa or less, and a temperature between about 25 °C and about 250 °C to fuse the first semiconductor device 200 to the first optical interposer 100. The first optical interposer 100 and the first semiconductor device 200 may then be subjected to a temperature at or above the eutectic point for material of the first bond pads 173 and the second bond pads 227, e.g., between about 150 °C and about 650 °C, to fuse the metal. In this manner, the first optical interposer 100 and the first semiconductor device 200 form a dielectric-to-dielectric and metal-to-metal bonded device. In some embodiments, the bonded devices are subsequently baked, annealed, pressed, or otherwise treated to strengthen or finalize the bond.

Additionally, while the above description describes a dielectric-to-dielectric and metal-to-metal bonding process, this is intended to be illustrative and is not intended to be limiting. In yet other embodiments, the first optical interposer 100 may be bonded to the first semiconductor device 200 by metal-to-metal bonding, or another bonding process. For example, the first semiconductor device 200 and the first optical interposer 100 may be bonded by metal-to-metal bonding that is achieved by fusing conductive elements. Any suitable bonding process may be utilized, and all such methods are fully intended to be included within the scope of the embodiments.

As illustrated, in some embodiments, the first semiconductor device 200 may not have a corresponding second bond pad 227 aligned to form a metal-to-metal bond with the reflective pad 174 along the first optical interposer 100. As a result, the reflective pad 174 may remain electrically isolated from the integrated circuitry of the first semiconductor device 200 and the first optical interposer 100. For example, due to the first semiconductor device 200 having a smaller width, the first semiconductor device 200 may not have components that overlap with the reflective pad 174 along the first optical interposer 100. In some embodiments (not specifically illustrated), the first semiconductor device 200 may overlap with the reflective pad 174 such that the second dielectric bond material 229 along the first semiconductor device 200 physically contacts an entirety of the outermost surface of the reflective pad 174. Similarly, one of the second bonding pads 227 along the first semiconductor device 200 may be a dummy pad and be aligned to form a metal-to-metal bond with the reflective pad 174 in the processes described above.

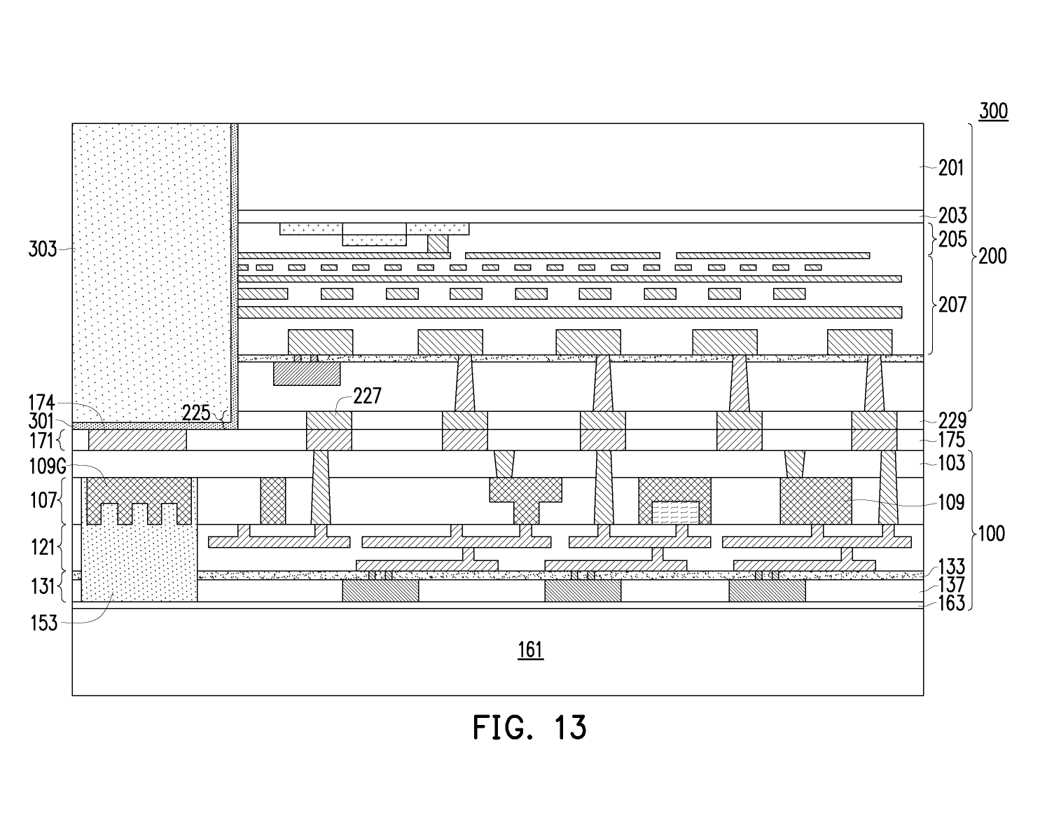

FIG. 13 illustrates forming a gap-fill material 303 over and around the first semiconductor device 200. For example, the gap-fill material 303 may be formed on and around an exposed surface of the first optical interposer 100 and exposed surfaces of the first semiconductor device 200, in accordance with some embodiments. As illustrated, in some embodiments, a liner layer 301 may first be deposited over the structure before depositing the gap-fill material 303. For example, the liner layer 301 may be formed of a dielectric material having good adhesion to the first optical interposer 100 and the first semiconductor device 200. In some embodiments, the liner layer 301 is formed of a nitride-containing material, such as silicon nitride, or an oxide-containing material, such as silicon oxide. For example, the liner layer 301 may be conformally deposited by a deposition process, such as ALD, CVD, or the like.

The gap-fill material 303 may be formed of a material different from the material of the liner layer 301. In some embodiments, the gap-fill material 303 may be formed of silicon oxide, silicon carbide, silicon nitride, silicon oxynitride, silicon oxycarbonitride, PSG, BSG, BPSG, or the like. For example, the gap-fill material 303 may be formed of any of the above oxide-containing materials, such as silicon oxide. The gap-fill material 303 may be formed using CVD, HDPCVD, flowable CVD, spin-on coating, or the like. The gap-fill material 303 may fill remainders of spaces between adjacent first semiconductor devices 200. After the liner layer 301 and the gap-fill material 303 are deposited, a planarization process, such as a CMP, a grinding process, an etch-back process, the like, or combinations thereof, is performed to remove excess portions of the liner layer 301 and the gap-fill material 303, thereby exposing the support substrate 201 of the first semiconductor device 200. In some embodiments, the planarization process may include thinning the support substrate 201 to achieve a desired thickness dimensions for the first semiconductor device 200 (e.g., the first optical package 300). Following the planarization process, the first semiconductor device 200, the gap-fill material 303, and the liner layer 301 may have substantially level surfaces.

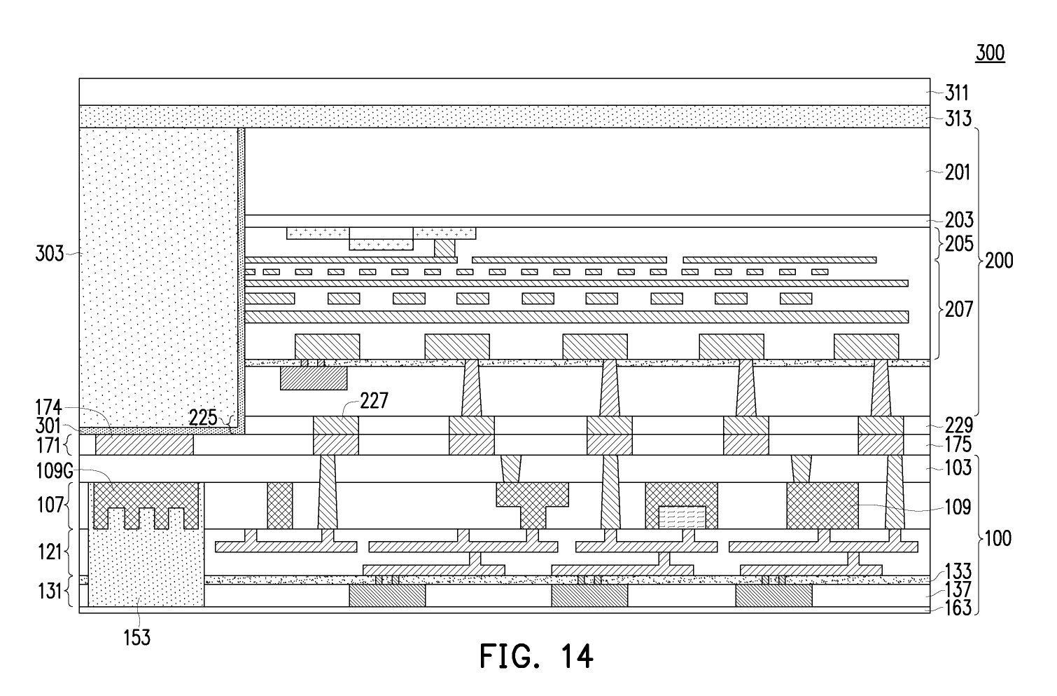

FIG. 14 illustrates that, once the gap-fill material 303 has been formed, a second carrier substrate 311 is attached over the first semiconductor device 200 and the first carrier substrate 161 is removed. In an embodiment, a bonding layer 313 is disposed along the second carrier substrate 311 to form a bond with the gap-fill material 303 and/or the first semiconductor device 200 (if exposed). For example, the bonding layer 313 may be formed with similar materials and processes as the adhesive layer 163 (or using one or more bonding layers) similarly as discussed above in connection with attaching the first carrier substrate 161 to the first optical interposer 100. In some embodiments (not specifically illustrated), the bonding layer 313 comprises a plurality of dielectric layers, wherein another bonding layer is first formed along the gap-fill material 303 and the support substrate 201 to facilitate dielectric-to-dielectric bonding between the respective bonding layers 313. Further, the various types of bonding between these components may also be performed similarly as described above in connection with attaching the first carrier substrate 161 to the first optical interposer 100.

In an embodiment, the first carrier substrate 161 is removed using a planarization process, such as a chemical mechanical polishing process, a grinding process, one or more etching processes, combinations of these, or the like. However, any suitable method may be used in order to remove the first carrier substrate 161. As illustrated, the adhesive layer 163 (or one or more of the bonding layers) may remain along the first optical interposer 100 and be exposed following removal of the first carrier substrate 161. In some embodiments (not specifically illustrated), the adhesive layer 163 is also removed, and the second passivation layer 137 and the dielectric fill layer 153 are exposed.

FIG. 15 illustrates forming an external connector layer 321, which includes a dielectric layer 325 and external connectors on the first optical interposer 100 of the first optical package 300, in accordance with some embodiments. For example, the dielectric layer 325 is deposited on the second passivation layer 137 (or the adhesive layer 163, if present) and the dielectric fill layer 153. In some embodiments, the dielectric layer 325 is formed of a photo-sensitive material such as polyimide, PBO, BCB, or the like, which may be patterned using a lithography mask. The dielectric layer 325 may be formed by spin coating, lamination, CVD, the like, or a combination thereof. The dielectric layer 325 is then patterned. The patterning forms openings exposing portions of the metal pads 153. The patterning may be by an acceptable process, such as by exposing and developing the dielectric layer 325 to light when the dielectric layer 325 is a photo-sensitive material or by etching using, for example, an anisotropic etch.

External connectors are then formed in the openings and may comprise under-bump metallizations (UBMs) 331 and conductive connectors 333. In some embodiments, the UBMs 331 have bulk portions on and extending along the major surface of the dielectric layer 325, and have via portions extending through the dielectric layer 325 to physically and electrically couple to the integrated circuitry, such as the metal pads 135 and/or the interconnect structure 121. The UBMs 331 may be formed of the same material as the metal pads 135 and/or the conductive material of the interconnect structure 121.

The UBMs 331 may comprise three layers of conductive materials, such as a layer of titanium, a layer of copper, and a layer of nickel. However, one of ordinary skill in the art will recognize that there are many suitable arrangements of materials and layers, such as an arrangement of chrome/chrome-copper alloy/copper/gold, an arrangement of titanium/titanium tungsten/copper, or an arrangement of copper/nickel/gold, that are suitable for the formation of the UBMs 331. Any suitable materials or layers of material that may be used for the UBMs 331 are fully intended to be included within the scope of the embodiments.

In an embodiment, the UBMs 331 are created by forming each layer over the metal pads 135 and the interconnect structure 121. The forming of each layer may be performed using a plating process, such as electrochemical plating, although other processes of formation, such as sputtering, evaporation, or PECVD process, may alternatively be used depending upon the desired materials.

The conductive connectors 333 are formed on the UBMs 331. The conductive connectors 333 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 333 may include a conductive material such as solder, copper, aluminum, gold, nickel, silver, palladium, tin, the like, or a combination thereof. In some embodiments, the conductive connectors 333 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 333 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

FIG. 15 further illustrates that, after forming the external connectors (e.g., the UBMs 331 and the conductive connectors 333), the dielectric layer 325 may be further patterned to form an opening 341 to the dielectric fill layer 153. In addition, an optical fiber 345 which is utilized as an optical input/output port to the first optical interposer 100, may be attached at the opening 341. In an embodiment, the optical fiber 345 is placed so as to optically couple the optical fiber 345 and an optical input such as the grating coupler 109G located within the first optical interposer 100. By positioning the optical fiber 345 in optical connection with the grating coupler 109G, optical signals leaving the optical fiber 345 are directed into the optical components of the first optical interposer 100. Similarly, the optical fiber 345 is positioned so that optical signals leaving the first optical interposer 100 are directed into the optical fiber 345 for transmission. However, any suitable location may be utilized.

In accordance with some embodiments, the optical fiber 345 may be held in place using, e.g., an optical glue 347 disposed in the opening 341 and along the dielectric fill layer 153. In some embodiments, the optical glue 347 comprises a polymer material such as epoxy-acrylate oligomers, and may have a refractive index between about 1 and about 3. However, any suitable material or method of securing the optical fiber 345 may be utilized.

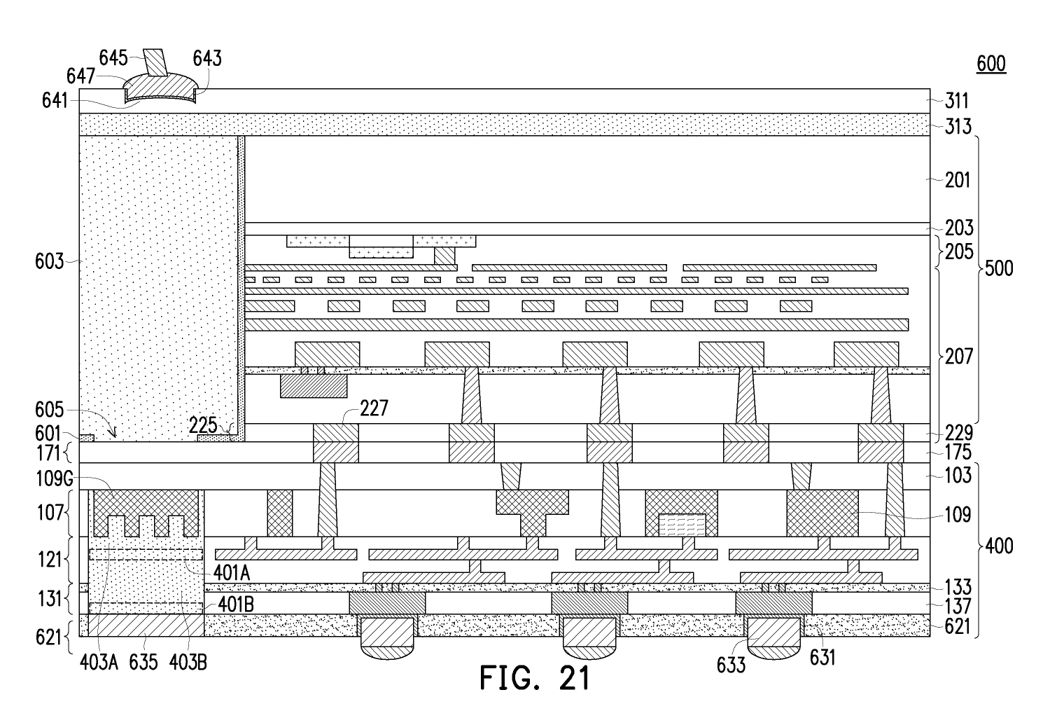

Various advantages are achieved through the layout of the first optical package 300. For example, the layout allows for the external input/output connections for both optical signals (e.g., through the optical fiber 345) and electrical signals (e.g., through the conductive connectors 333) being along a same side of the first optical package 300. In addition, the optical signal between the optical fiber 345 and the grating couplers 109G may pass a shorter distance through a partial thickness of the first optical interposer 100 as compared with a longer distance through entire thicknesses of the second carrier substrate 311, the first semiconductor device 200 (e.g., the gap-fill material 303), and the first and second bond layers 171, 225. As further illustrated, the optical fiber 345 may be directed into the first optical package 300 without a lens (for comparison, see FIG. 21 and related discussion). Moreover, the first optical interposer 100 may be formed without a back-side redistribution structure and passivation layers, which decreases the overall thickness of the first optical interposer 100 as well as the first optical package 300.

Although not specifically illustrated, the first optical package 300 may subsequently be singulated and attached to a package substrate, such as a printed circuit board (PCB), to be incorporated in a semiconductor package or electronic device. For example, the conductive connectors 333 may be electrically coupled to conductive features along a package substrate. Due to the location of the opening 341 in the dielectric layer 325, an edge of said package substrate may stop short of the opening 341 or said package substrate may be configured to assist in securing the optical fiber 345 in relation to the opening 341 in alternative to or in conjunction with the optical glue 347.

For example, once the first optical package 300 has been formed, the first optical package 300 may be attached to an interposer substrate that is used to couple the first optical package 300 with other devices to form, for example, a chip-on-wafer-on-substrate (CoWoS^{®}) package. In an embodiment, the interposer substrate 1301 comprises a semiconductor substrate, an interconnect structure, through vias, and external connectors for attachment and electrical connection to other devices.

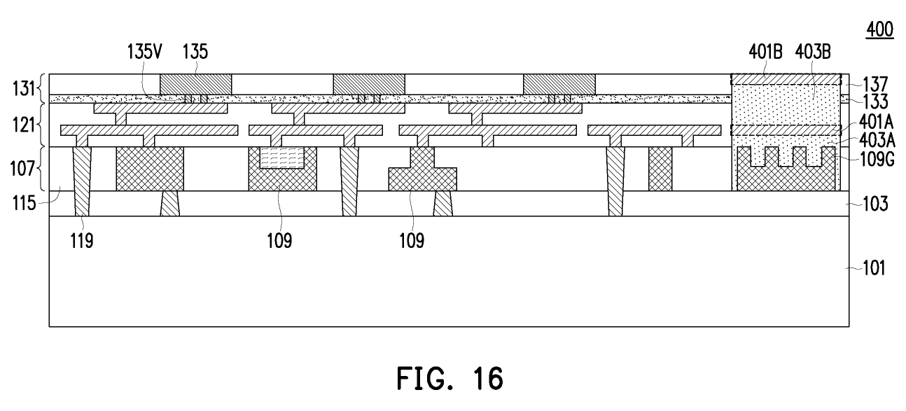

FIGS. 16-21 and the related discussion refer to embodiments of a second optical interposer 400 and a second semiconductor device 500 combining to form a second optical package 600. These embodiments of the second optical package 600 may be formed similarly and analogously as described above in connection with the first optical package 300, unless otherwise stated. In addition, the second optical interposer 400 and the second semiconductor device 500 may be formed similarly as described above in connection with the first optical interposer 100 and the first semiconductor device 200, respectively. As discussed in greater detail below, formation and structure of the second optical package 600 may differ from that of the first optical package 300 due to variations related to accommodating signals being transmitted to and received from an optical fiber located on an opposite side of the second optical package 600 as compared to the first optical package 300.

FIG. 16 illustrates a second optical interposer 400 formed similarly as an intermediate stage of the first optical interposer 100 after forming the opening 151 (see FIG. 7). Similarly, in accordance with some embodiments, an opening is optionally formed through the region 145 which may expose the grating couplers 109G. The opening is filled with a reflective pad 401 and a dielectric fill layer 403 are formed in the opening.

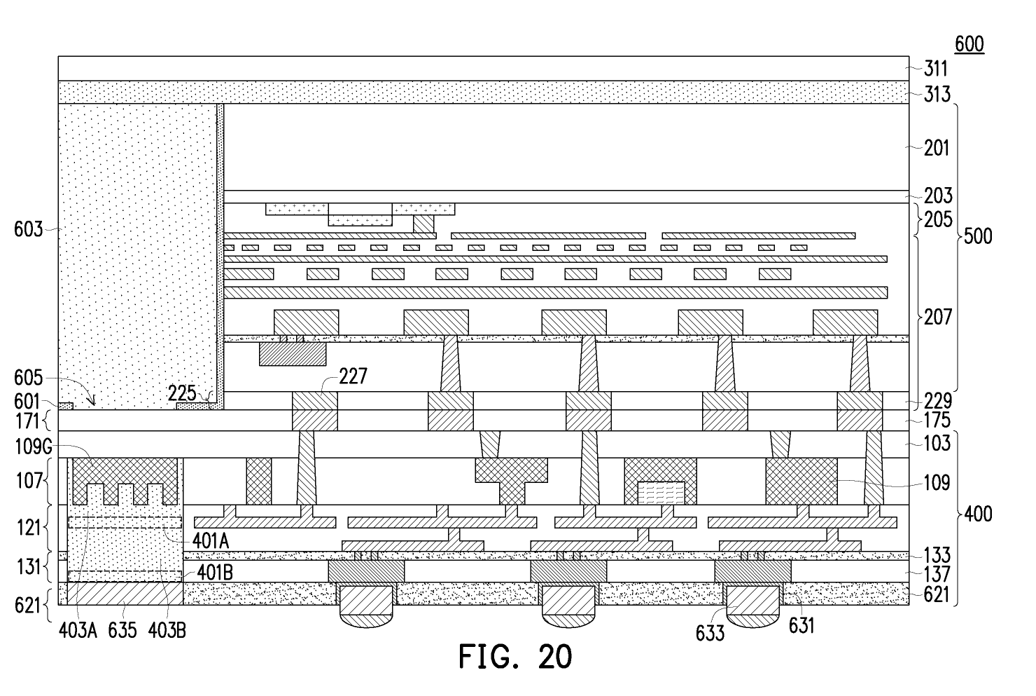

For example, the reflective pad 401 may be a proximal reflective pad 401A formed at a location proximal to the grating couplers 109G, or the reflective pad 401 may be a distal reflective pad 401B formed at a greater distance from the grating couplers 109G. However, the reflective pad 401 may be formed at any suitable distance in relation to the grating couplers 109G. In embodiments in which the opening is entirely filled by the dielectric fill layer 403, a reflective pad is formed over the grating couplers 109G in a subsequent step (see FIG. 20).

In accordance with embodiments, the dielectric fill layer 403 is formed in multiple steps. For example, the dielectric fill layer 403 may be formed in the opening over and around the grating couplers 109G, similarly as described above in connection with the dielectric fill layer 153 of the first optical interposer 100 (see FIG. 8). The dielectric fill layer 403 may then be planarized to be level with a surface of the second optical interposer 400 and recessed to a desired depth for the reflective pad 401. The reflective pad 401 is then formed by depositing a conductive material in the recess using a plating process, such as an electroplating or electroless plating process, or the like. The conductive material may include a reflective metal such as copper, however, any suitable reflective material or combination of materials (e.g., alloys) may be used.

If necessary, after forming the reflective pad 401, a remainder of the opening may be refilled with the dielectric fill layer 403. As illustrated, in embodiments in which the proximal reflective pad 401A is formed in the opening, the dielectric fill layer 403 will comprise two portions. That is, the dielectric fill layer 403 will include a proximal dielectric fill layer 403A and a distal dielectric fill layer 403B on opposing sides of the proximal reflective pad 401A. In some embodiments, the distal reflective pad 401B may be formed at the top of the opening, such that an additional component of the dielectric fill layer 403 is not necessary to fill any remainder of the opening above the reflective pad 401. After an upper portion of the opening is filled with the reflective material, a planarization process may be performed to remove excess reflective material from the upper surface of the optical interposer (e.g., of the metal pad layer 131). As a result, the distal reflective pad 401B will have a level surface with the metal pad layer 131.

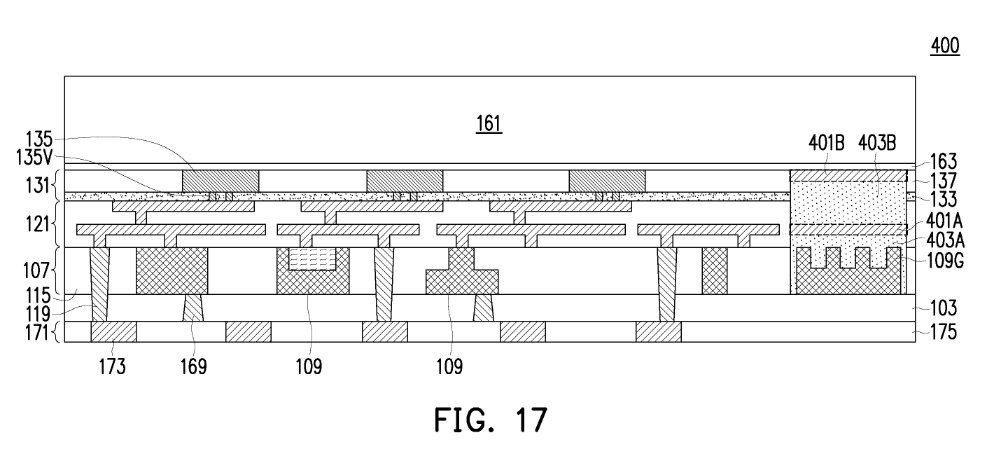

FIG. 17 illustrates subsequent processes performed on the second optical interposer 400, similarly as described above in connection with the first optical interposer 100. For example, the first carrier substrate 161 is attached and the substrate 101 is removed from the second optical interposer 400 (see FIG. 9). In addition, the TDVs 119 may be exposed and the back-side TDVs 169 may be formed to electrically connect the optical components 109 and the interconnect structure 121 to a back-side of the second optical interposer 400 (see FIG. 9). Further, the first bond layer 171 may then be formed over and electrically connected to the TDVs 119 and the back-side TDVs 169 (see FIG. 10).

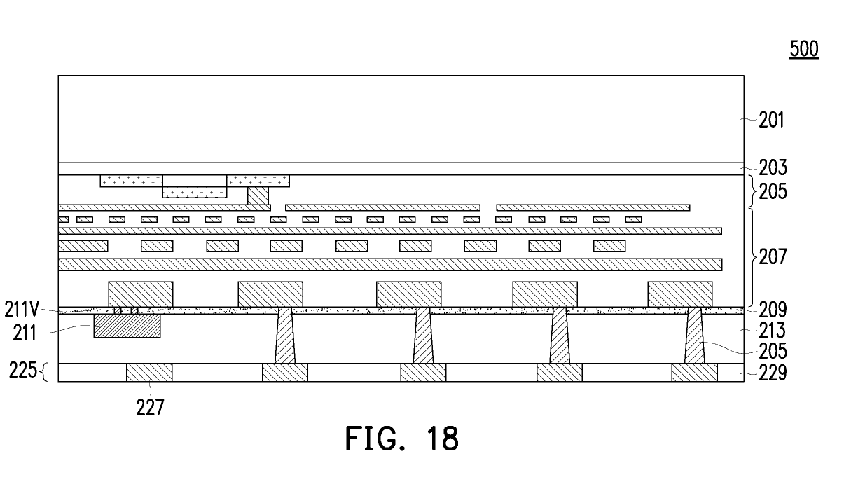

FIG. 18 illustrates a second semiconductor device 500 formed similarly as described above in connection with the first semiconductor device 200. In some embodiments, the second semiconductor device 500 may be an EIC device formed at wafer level. As discussed in greater detail below, the second semiconductor device 500 may be singulated from the wafer form and attached to the second optical interposer to form a second optical package 600.

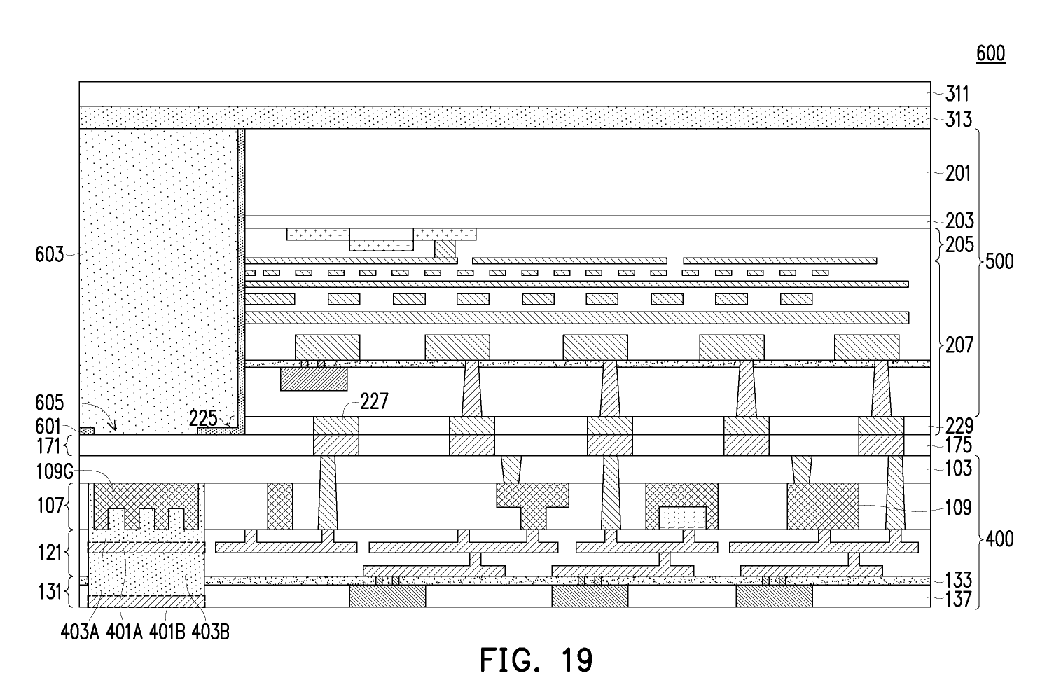

FIG. 19 illustrates bonding of the second semiconductor device 500 (e.g., singulated EIC device from the wafer) to the second optical interposer 400 (e.g., PIC device remaining as part of a wafer). In addition, a gap-fill material 603 (e.g., optionally including a liner layer 601) is formed on and around an exposed surface of the second optical interposer 400 and exposed surfaces of the second semiconductor device 500, similarly as described above in connection with forming the gap-fill material 303 (and liner layer 301) of the first optical package 300 (see FIG. 13), unless specified below. Further, the second carrier substrate 311 is attached over the first semiconductor device 200 and the first carrier substrate 161 is removed, similarly as described above in connection with the first optical package (see FIG. 14). Similarly, the bonding layer 313 is disposed along the second carrier substrate 311 to form a bond with the gap-fill material 303 and/or the second semiconductor device 500 (if exposed).

In accordance with some embodiments, the gap-fill material 603 and the liner layer 601 are formed such that light of a desired range of wavelengths may pass through these layers to reach the grating couplers 109G. In the illustrated embodiment, the liner layer 601 may be patterned or deposited to have an opening 605 directly above the grating couplers 109G. In some embodiments, the liner layer 601 is formed of a material that is transparent or translucent to the desired range(s) of wavelengths and/or deposited sufficiently thin to be substantially and/or or sufficiently transparent. Further, in some embodiments, the gap-fill material 603 may be formed around the second semiconductor device 500, and deposition of the liner layer 601 may be omitted.

FIG. 20 illustrates forming an external connector layer 621, which includes a dielectric layer 625 and external connectors (e.g., UBMs 631 and conductive connectors 633) on the second optical interposer 400 of the second optical package 600, similarly as discussed above in connection with the first optical interposer 100 of the first optical package 300 (see FIG. 15). As further illustrated, in some embodiments, the reflective pad 401 may not have been formed in the second optical interposer 400 as discussed above in relation to FIG. 16. In such embodiments, a reflective pad 615 may be formed before, after, or in parallel with the UBMs 631. For example, the reflective pad 635 may be formed in the external connector layer 621 simultaneously with and of a same material as used for the UBMs 631. In some embodiments, before or after forming the UBMs 631, an opening may be patterned in the dielectric layer 625 of the external connector layer 621, and the reflective pad 635 may be formed similarly as described above in connection with the reflective pad 401.

FIG. 21 illustrates formation of a lens 641 within the second carrier substrate 311. In an embodiment, a photosensitive material (not separately illustrated) may be deposited, exposed, developed, and reflowed in order to form the desired shape and contours for the lens 641 in a mask. Once the mask is present, the formation of the lens 641 may be performed using, for example, an anisotropic etching process, such as a reactive ion etch, that uses the mask as a sacrificial mask. In particular, as the etching process progresses to etch the second carrier substrate 311, the etching process will also etch the material of the mask. As the thinner portions of the mask are removed, additional portions of the second carrier substrate 311 are exposed to the etching process, until some, most, or all of the mask is consumed. In this fashion, the shape of the mask is translated to the second carrier substrate 311, thereby forming the lens 641 within the second carrier substrate 311. However, any suitable process may be utilized.

In some embodiments, an anti-reflective coating (ARC) 643 may be formed over the lens 641. In an embodiment the ARC 643 may be one or more layers of materials which help to prevent undesired reflections as light is focused through the lens 641. In a particular embodiment, the one or more layers of materials may be materials such as silicon oxide, silicon nitride, combinations of these, or the like, formed using processes such as chemical vapor deposition, atomic layer deposition, physical vapor deposition, oxidation, nitridation, combinations of these, or the like.

In a particular embodiment the ARC 643 may be formed using a first layer of silicon oxide and a first layer of silicon nitride formed over the first layer of silicon oxide. A second layer of silicon oxide and a second layer of silicon nitride are deposited over the first layer of silicon oxide and the first layer of silicon nitride, forming an alternating stack of silicon oxide and silicon nitride. However, any suitable combinations of materials may be utilized. It should further be noted that the lens 641 and the ARC 643 may be formed before or after attachment of the second carrier substrate 311 over the second semiconductor device 500.

FIG. 21 further illustrates placement of an optical fiber 645 which is utilized as an optical input/output port to the second optical package (e.g., the second optical interposer 400). In an embodiment, the optical fiber 645 is placed so as to optically couple the optical fiber 645 and an optical input such as the grating couplers 109G located within the second optical interposer 400. By positioning the optical fiber 645 in optical connection with the grating coupler 109G, optical signals leaving the optical fiber 645 are directed through the lens 641 of the second carrier substrate 311, the gap-fill material 603 (and the liner layer 601, if present), and other components and into the grating couplers 109G of the second optical interposer 400. Similarly, the optical fiber 645 is positioned so that optical signals leaving the second optical interposer 400 are directed into the optical fiber 645 for transmission. However, any suitable location may be utilized.

The optical fiber 645 may be held in place using, e.g., an optical glue 647. In some embodiments, the optical glue 647 comprises a polymer material such as epoxy-acrylate oligomers, and may have a refractive index between about 1 and about 3. However, any suitable material may be utilized.

Various advantages are achieved through the layout of the second optical package 600. For example, the layout allows for the optical signal between the optical fiber 645 and the grating couplers 109G to pass a shorter distance through a thickness of the second semiconductor device 500 and a minority portion of a thickness of the second optical interposer 400 (e.g., the first bond layer 171 and the first insulator layer 103) rather than a longer distance through a thickness of the second semiconductor device 500 in addition to a majority portion of the thickness of the second optical interposer 400. As further illustrated, this layout allows for multiple locations for the reflective pad (e.g., the proximal reflective pad 401A, the distal reflective pad 401B, or the reflective pad 635) depending on manufacturing considerations and conveniences.

It should be noted that, while a number of configurations have been presented in the above descriptions, these precise configurations are intended to be illustrative only and are not intended to limit the embodiments to these precise configurations. Rather, any suitable configurations, such as a stack of the first or second semiconductor devices 200, 500 and/or a stack of the first or second optical interposers 100, 400 may be utilized to form the first or second optical packages 300, 600, in accordance with various embodiments. Any suitable configuration may be utilized, and all such configurations are fully intended to be included within the scope of the embodiments.

By utilizing the above described layouts for the first optical package 300 and the second optical package 600, advantages and efficiencies may be achieved in the resulting devices. In particular, a greater variety of package layouts allow for flexibility in the locations for the optical input/output signals. In addition, those optical input/output signals may follow a shorter path to or from the grating couplers 109G, which improves efficiency and reliability of the device. Further, the optical interposers 100, 400 may be thinner without requiring a back-side redistribution structure, which may result in thinner optical packages 300, 600, respectively.

In an embodiment, a method includes: forming an optical interposer, forming the optical interposer comprising: forming an optical device layer over a front-side of a first substrate, the optical device layer comprising a grating coupler; forming a first interconnect structure over the optical device layer, the first interconnect structure comprising conductive features and dielectric layers; etching an opening through the dielectric layers to expose the grating coupler; filling the opening with an oxide layer; forming a first bond layer over a back-side of the first substrate, the first bond layer comprising first bond pads and a first dielectric bond layer; attaching a semiconductor device to the optical interposer, the semiconductor device comprising: an active device layer over a front-side of a second substrate; a second interconnect structure over the active device layer; and a second bond layer over the second interconnect structure, the second bond layer comprising second bond pads and a second dielectric bond layer; and forming external connectors over and electrically connected to the first interconnect structure of the optical interposer. In another embodiment, the first bond layer comprises a reflective pad, and wherein in a plan view the reflective pad overlaps the grating coupler. In another embodiment, attaching the semiconductor device comprises dielectric-to-dielectric and metal-to-metal bonding. In another embodiment, the first substrate comprises a silicon-on-insulator substrate. In another embodiment, the method further includes: before forming the first interconnect structure, forming a through device via extending through the optical device layer; and removing at least a portion of the back-side of the first substrate to expose the through device via. In another embodiment, the method further includes: forming a gap-fill material over and around the semiconductor device. In another embodiment, the method further includes: attaching a carrier substrate over the semiconductor device, the semiconductor device being interposed between the carrier substrate and the optical interposer; and forming a lens in the carrier substrate. In another embodiment, the grating coupler is configured to receive and transmit a range of light wavelengths, and wherein a region extending from the lens to the grating coupler is transparent to the range of light wavelengths.

In an embodiment, a method includes: forming a device layer over a front-side of a first substrate, the device layer comprising an optical input/output device and an optical waveguide, the optical input/output device being configured to receive a range of light wavelengths; forming a through device via extending through at least part of the device layer and the first substrate; forming an interconnect structure over a front-side of the device layer; forming an opening through the interconnect structure to expose the optical input/output device; depositing an insulating material in the opening, the insulating material being transparent to the range of light wavelengths; attaching a first carrier over the interconnect structure; exposing the through device via from a back-side of the first substrate; forming a first bond layer over and electrically connected to the exposed through device via; bonding the first bond layer to an electronic integrated circuit device, the electronic integrated circuit device comprising a second bond layer; attaching a silicon substrate over the electronic integrated circuit device; forming an external connector layer over and electrically connected to the interconnect structure; and forming a lens in the silicon substrate, a region extending from the lens to the optical input/output device being transparent to the range of light wavelengths. In another embodiment, depositing the insulating material comprises: forming a first portion of the insulating material in the opening; forming a first reflective pad over the first portion of the insulating material; and forming a second portion of the insulating material to fill a remainder of the opening. In another embodiment, depositing the insulating material comprises: filling the opening with the insulating material; etching the insulating material to form a recess; and filling the recess with a reflective material to form a second reflective pad. In another embodiment, the external connector layer comprises under-bump metallizations and a third reflective pad. In another embodiment, forming the external connector layer comprises forming the third reflective pad in parallel with the under-bump metallizations. In another embodiment, the insulating material comprises an oxide.

In an embodiment, an optical package includes: an optical interposer, comprising: an external connector layer; a first interconnect structure over the external connector layer, the first interconnect structure comprising conductive features embedded in dielectric layers; an active device layer over the first interconnect structure, the active device layer comprising a grating coupler; a dielectric substrate over the active device layer; a first bond layer over the dielectric substrate; and a reflective pad, in a plan view the reflective pad overlapping the grating coupler; and a semiconductor device attached to the first bond layer of the optical interposer, the semiconductor device comprising a second bond layer, a second interconnect structure, and an electronic device layer. In another embodiment, in the plan view the dielectric layers overlapping the grating coupler are free of the conductive features. In another embodiment, the reflective pad is within the first bond layer. In another embodiment, the reflective pad is within the external connector layer. In another embodiment, the dielectric layers comprise a continuous oxide region disposed around the grating coupler. In another embodiment, the reflective pad is within the continuous oxide region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an optical interposer, forming the optical interposer comprising:
forming an optical device layer over a front-side of a first substrate, the optical device layer comprising a grating coupler;
forming a first interconnect structure over the optical device layer, the first interconnect structure comprising conductive features and dielectric layers;
etching an opening through the dielectric layers to expose the grating coupler;
filling the opening with an oxide layer;
forming a first bond layer over a back-side of the first substrate, the first bond layer comprising first bond pads and a first dielectric bond layer;
attaching a semiconductor device to the optical interposer, the semiconductor device comprising:
an active device layer over a front-side of a second substrate;
a second interconnect structure over the active device layer; and
a second bond layer over the second interconnect structure, the second bond layer comprising second bond pads and a second dielectric bond layer; and
forming external connectors over and electrically connected to the first interconnect structure of the optical interposer.

2. The method of claim 1, wherein the first bond layer comprises a reflective pad, and wherein in a plan view the reflective pad overlaps the grating coupler.

3. The method of claim 1, wherein attaching the semiconductor device comprises dielectric-to-dielectric and metal-to-metal bonding.

4. The method of claim 1, wherein the first substrate comprises a silicon-on-insulator substrate.

5. The method of claim 4, further comprising:
before forming the first interconnect structure, forming a through device via extending through the optical device layer; and
removing at least a portion of the back-side of the first substrate to expose the through device via.

6. The method of claim 1, further comprising:
forming a gap-fill material over and around the semiconductor device.

7. The method of claim 6, further comprising:
attaching a carrier substrate over the semiconductor device, the semiconductor device being interposed between the carrier substrate and the optical interposer; and
forming a lens in the carrier substrate.

8. The method of claim 7, wherein the grating coupler is configured to receive and transmit a range of light wavelengths, and wherein a region extending from the lens to the grating coupler is transparent to the range of light wavelengths.

9. A method comprising:
forming an active layer over a first substrate, the active layer comprising a grating coupler;
forming an interconnect structure over the active layer, the interconnect structure comprising conductive features, wherein a region of the interconnect structure overlying the grating coupler is free of the conductive features;
forming an opening through the region to expose the grating coupler;
filling the opening with a dielectric fill layer that is transparent to an optical signal;
bonding a semiconductor device to a back-side of the first substrate opposite the interconnect structure; and
attaching an optical fiber to the dielectric fill layer, wherein the optical fiber is optically coupled to the grating coupler through the dielectric fill layer.

10. The method of claim 9, wherein bonding the semiconductor device comprises:
forming a first bond layer over the back-side of the first substrate; and
bonding the first bond layer to a second bond layer of the semiconductor device.

11. The method of claim 10, wherein the first bond layer comprises a first dielectric bond material and first bond pads, wherein the second bond layer comprises a second dielectric bond material and second bond pads, wherein bonding the first bond layer to the second bond layer comprises dielectric-to-dielectric and metal-to-metal bonding.

12. The method of claim 10, wherein forming the first bond layer comprises forming a reflective pad over the grating coupler, the reflective pad reflecting optical signals to or from the grating coupler.

13. The method of claim 12, wherein the reflective pad is located directly over the grating coupler, and wherein a width of the reflective pad is greater than or equal to a footprint of the grating coupler.

14. The method of claim 12, wherein the reflective pad is electrically isolated from the semiconductor device.

15. A method comprising:
forming an optical interposer comprising an active layer and an interconnect structure over the active layer, wherein the active layer comprises a grating coupler;
bonding a semiconductor device to a back-side of the optical interposer, the semiconductor device comprising active devices;
forming a gap-fill material around the semiconductor device;
forming conductive connectors over a front-side of the optical interposer opposite the semiconductor device; and
attaching an optical fiber to the front-side of the optical interposer, the optical fiber optically coupled to the grating coupler and disposed on a same side of the optical interposer as the conductive connectors.

16. The method of claim 15, wherein forming the gap-fill material comprises:
depositing a liner layer over the semiconductor device; and
depositing the gap-fill material over the liner layer, the gap-fill material comprising a different material than the liner layer.

17. The method of claim 16, wherein bonding the semiconductor device comprises:
forming a first bond layer over the back-side of the optical interposer; and
bonding the first bond layer to a second bond layer of the semiconductor device, wherein the first bond layer comprises a reflective pad, wherein the reflective pad overlaps the grating coupler.

18. The method of claim 17, wherein the semiconductor device has a width smaller than a width of the optical interposer, and wherein the semiconductor device does not overlap the reflective pad.

19. The method of claim 17, wherein the reflective pad is electrically isolated from the semiconductor device.

20. The method of claim 15, wherein forming the interconnect structure comprises forming the interconnect structure such that a region overlying the grating coupler is free of conductive features, further comprising:
forming an opening through the region to expose the grating coupler; and
filling the opening with a dielectric fill layer that is transparent to an optical signal, wherein the optical fiber is optically coupled to the grating coupler through the dielectric fill layer.
